(19) United States
(12) Patent Application Publication
(10) Pub. No.: US 2014/0037862 A1
(43) Pub. Date: Feb. 6, 2014

(54) METHOD FOR MANUFACTURING PRINTED CIRCUIT BOARD

(71) Applicant: SAMSUNG ELECTRO-MECHANICS CO., LTD., Gyunggi-do (KR)

(72) Inventors: Chang Bo Lee, Gyunggi-do (KR); Do Wan Kim, Gyunggi-do (KR); Cheol Ho Choi, Gyunggi-do (KR); Chang Sup Ryu, Gyunggi-do (KR)

(73) Assignee: SAMSUNG ELECTRO-MECHANICS CO., LTD., Gyunggi-do (KR)

(21) Appl. No.: 13/671,377

(22) Filed: Nov. 7, 2012

(30) Foreign Application Priority Data
Aug. 3, 2012 (KR) 10-2012-0085270

(51) Int. Cl. H05K 3/18

(52) U.S. Cl. CPC H05K 3/18
USPC 427/555; 205/125

(57) ABSTRACT

Disclosed herein is a method for manufacturing a printed circuit board for forming a solder resist of an outermost layer having a step structure by performing laser machining or exposing and developing processes.

### CROSS REFERENCE TO RELATED APPLICATION

This application claims the benefit of Korean Patent Application No. 10-2012-0085270, filed on Aug. 3, 2012, entitled “Method For Manufacturing of Printed Circuit Board”, which is hereby incorporated by reference in its entirety into this application.

### BACKGROUND OF THE INVENTION

1. Technical Field

The present invention relates to a method for manufacturing a printed circuit board.

2. Description of the Related Art

In addition to Patent Document 1, a printed circuit board has been variously used for several applications such various electronic products, in particular, mobile electronic products, and the like.

As applications of the printed circuit board have been expanded, a structure of the printed circuit board has been diversified.

For example, due to a demand for thinness and miniaturization of mobile electronic products, packaging companies tend to enhance the thinness of a semiconductor package substrate so as to increase a packaging density and reduce a thickness of a package.

### RELATED ART DOCUMENT

### Patent Document

### (Patent Document 1) US 2008-0053688 A1

### SUMMARY OF THE INVENTION

The present invention has been made in an effort to provide a method for manufacturing a printed circuit board for forming a solder resist of an outermost layer having a step structure.

According to a preferred embodiment of the present invention, there is provided a method for manufacturing a printed circuit board, including: preparing a base substrate on which a circuit layer segmented into a first surface treating area and a second surface treating area is formed; forming a solder resist layer on the base substrate, including the circuit layer; forming a first open part of the first surface treating area and a first open part of the second surface treating area by performing exposing and developing processes on solder resist layers corresponding to the first surface treating area and the second surface treating area; forming a step open part of the first surface treating area exposing the circuit layer of the first surface treating area by performing the exposing and developing processes of the first open part of the first surface treating area; forming the first surface treating layer on the exposed circuit layer of the first surface treating area; forming a second open part of the second surface area by performing laser machining on the first open part of the second surface treating area to expose the circuit layer of the second surface treating area; and forming the second surface treating layer on the exposed circuit layer of the second surface treating area, wherein the solder resist layer is formed with a step shape corresponding to the step open part of the first surface treating area.

The method for manufacturing a printed circuit board may further include: after the forming of the solder resist layer and before the forming of the first open part of the first surface treating area and the first open part of the second surface treating area, removing the solder resist layer based on a thickness direction of a substrate by performing the exposing and developing processes on the overall surface of an upper portion of the solder resist layer to arbitrarily reduce a thickness thereof.

The method for manufacturing a printed circuit board may further include: after the forming of the first surface treating layer and before the forming of the second open part of the second surface treating area, forming a mask layer having an open part corresponding to the second open part of the second surface treating area on the solder resist layer.

The mask layer may be formed of a dry film.

In the forming of the step open part of the first surface treating area, the step open part of the first surface treating area may be formed so as to expose an upper surface and a side of the circuit layer of the first surface treating area.

In the forming of the second open part of the second surface treating area, the second open part of the second surface treating area may be formed to be equal to a size of the first open part of the second surface treating area based on a length direction of the substrate.

In the forming of the second open part of the second surface treating area, the second open part of the second surface treating area may be formed to be smaller than a size of the first open part of the second surface treating area based on a length direction of the substrate.

The method for manufacturing a printed circuit board may further include: after the forming of the second opening part of the second surface treating area and before the forming of the second surface treating layer on the exposed circuit layer of the second surface treating area, performing a desmear process on the first open part and the second open part of the second surface treating area.

According to another preferred embodiment of the present invention, there is provided a method for manufacturing a printed circuit board, including: preparing a base substrate on which a circuit layer segmented into a first surface treating area and a second surface treating area is formed; forming a solder resist layer on the base substrate, including the circuit layer; forming a first open part of the first surface treating area and a first open part of the second surface treating area by performing laser machining on solder resist layers corresponding to the first surface treating area and the second surface treating area; forming a step open part of the first surface treating area exposing the circuit layer of the first surface treating area by performing the laser machining on the first open part of the first surface treating area; forming the first surface treating layer on the exposed circuit layer of the first surface treating area; forming a second open part of the second surface treating area by performing laser machining on the first open part of the second surface treating area to expose the circuit layer of the second surface treating area; and forming the second surface treating layer on the exposed circuit layer of the second surface treating area; wherein the solder resist layer is formed with a step shape corresponding to the step open part of the first surface treating area.

The method for manufacturing a printed circuit board may further include: after the forming of the solder resist layer and before the forming of the first open part of the first surface treating area and the first open part of the second surface treating area, removing the solder resist layer based on a thickness direction of a substrate by performing the exposing and developing processes on the overall surface of an upper portion of the solder resist layer to arbitrarily reduce a thickness thereof.

The method for manufacturing a printed circuit board may further include: after the forming of the solder resist layer and before the forming of the first open part of the first surface treating area and the first open part of the second surface treating area, removing the solder resist layer based on a thickness direction of a substrate by performing the laser machining on the overall surface of an upper portion of the solder resist layer to arbitrarily reduce a thickness thereof.

The method for manufacturing a printed circuit board may further include: after the forming of the first surface treating layer and before the forming of the second open part of the second surface treating area, forming a mask layer having an open part corresponding to the second open part of the second surface treating area on the solder resist layer.

The mask layer may be formed of a dry film.

In the forming of the step open part of the first surface treating area, the step open part of the first surface treating area may be formed so as to expose an upper surface and a side of the circuit layer of the first surface treating area.

In the forming of the second open part of the second surface treating area, the second open part of the second surface treating area may be formed to be equal to a size of the first open part of the second surface treating area based on a length direction of the substrate.

In the forming of the second open part of the second surface treating area, the second open part of the second surface treating area may be formed to be smaller than a size of the first open part of the second surface treating area based on a length direction of the substrate.

The method for manufacturing a printed circuit board may further include: after the forming of the step opening part of the first surface treating area and before the forming of the first surface treating layer on the exposed circuit layer of the first surface treating area, performing a desmear process on the step open part of the first surface treating area.

The method for manufacturing a printed circuit board may further include: after the forming of the second opening part of the second surface treating area and before the forming of the second surface treating layer on the exposed circuit layer of the second surface treating area, performing a desmear process on the first open part and the second open part of the second surface treating area.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 7 are process cross-sectional views for describing a method for manufacturing a printed circuit board according to an exemplary embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Method for Manufacturing Printed Circuit Board

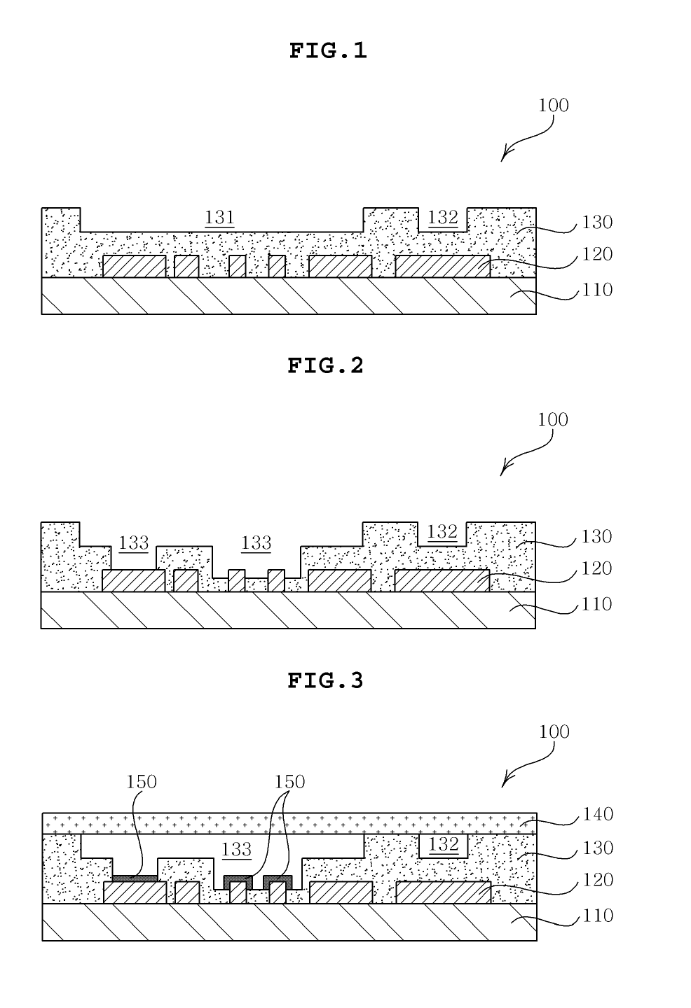

FIGS. 1 to 7 are process cross-sectional views for describing a method for manufacturing a printed circuit board according to an exemplary embodiment of the present invention.

First, as shown in FIG. 1, a base substrate 110 on which a circuit layer 120 segmented into a first surface treating area and a second surface treating area is formed may be prepared.

The base substrate 110 may be a printed circuit board on which a general insulating layer used as a core substrate in a printed circuit board field or a circuit including a connection pad of one or more layer on an insulating layer is formed.

As the insulating layer, a resin insulating layer may be used As the resin insulating layer, thermosetting resin such as epoxy resin, thermoplastic resin such as polyimide, resin having reinforcing materials such as a glass fiber or an inorganic filler impregnated thereinto, for example, prepreg, and the like, may be used In addition, thermosetting resin and/or photocurable resin, and the like, may be used, but the exemplary embodiment of the present invention are not particularly limited thereto.

A solder ball as an external connection terminal is formed on the connection pad by a subsequent process and a semiconductor device or external components and an inner-layer circuit are electrically connected by the solder ball.

The circuit including the connection pad may be applied without being limited if a conductive metal for a circuit may be used in the printed circuit board field. Typically, copper may be used in the printed circuit board.

Next, as shown in FIG. 1, a solder resist layer 130 may be formed on the base substrate 110, including the circuit layer 120.

The solder resist layer 130 serves as a protective layer protecting an outermost layer circuit and is formed to implement electrical insulation and may be formed with an open part so as to expose a connection pad at an outermost layer. As known to those skilled in the art, the solder resist layer 130 may be formed of for example, photocurable resin, thermosetting resin, a complex material of the photocurable resin and the thermosetting resin, and the like, but the exemplary embodiment of the present invention is not particularly limited thereto.

Next, although not shown, the overall surface of the upper portion of the solder resist layer 130 is subjected to the exposing and developing processes to remove the solder resist layer 130 based on a thickness direction of the substrate, thereby making it possible to arbitrarily reduce a thickness thereof and omitting the corresponding processes according to the operator demand.

Meanwhile, the overall surface of the upper portion of the solder resist layer 130 is subjected to the laser machining to remove the solder resist layer 130 based on the thickness direction of the substrate, thereby making it possible to arbitrarily reduce the thickness thereof.

The process of reducing the thickness of the foregoing solder resist layer 130 is to improve the convenience of the laser machining that is progressed later.

Next, as shown in FIG. 1, the solder resist layers 130 corresponding to the first surface treating area and the second surface treating area are subjected to the exposing and developing processes to form a first open part 131 on the first surface treating area and a first open part 132 on a second surface treating area.

Meanwhile, the solder resist layer 130 corresponding to the first surface treating area and the second surface treating area may be subjected to the laser machining to form the first open part 131 on the first surface treating area and the first open part 132 on the second surface treating area.

Next, as shown in FIG. 2, the first open part (131 of FIG. 1) on the first surface treating area may be subjected to the exposing and developing process to form a step open part 133 on the first surface treating area exposing the circuit layer 120 of the first surface treating area.

In this case, as shown in FIG. 7, it is possible to form the step open part 133 on the first surface treating area so as to expose (area A of FIG. 7) the upper surface and side of the circuit layer 120 of the first surface treating area.

Meanwhile, the first open part (131 of FIG. 1) on the first surface treating area may be subjected to the laser machining to form the step open part 133 on the first surface treating area exposing the circuit layer 120 of the first surface treating area.

Next, the step open part 133 on the first surface treating area may be subjected to a desmear process.

Next, as shown in FIG. 3, a first surface treating layer 150 may be formed on the exposed circuit layer 120 of the first surface treating area.

In this case, for the convenience of explanation, FIG. 3 shows that both of the first surface treating layer 150 and a mask layer 140 are formed, but it is apparent that the surface treating layer 150 is first formed and then, the mask layer 140 is formed through a post-process.

The first surface treating layer 150 is not particularly limited to if known to those skilled in the art and may be formed, for example, by electro gold plating, immersion gold plating, Organic Solderability Preservative (OSP), immersion tin plating, immersion silver plating, electroless nickel and immersion gold (ENIG), Direct Immersion Gold (DIG) plating, Hot Air Solder Leveling (HASL), Electroless Nickel Electroless Palladium Immersion Gold (ENEPIG), or Electroless Palladium Immersion Gold (EPIG), and the like.

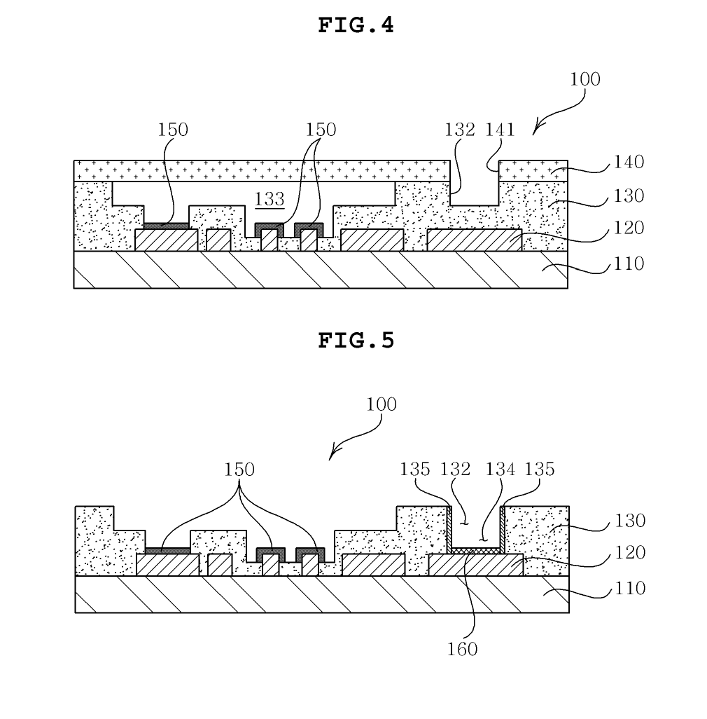

Next, as shown in FIGS. 3 and 4, the mask layer 140 having the open part 141 corresponding to a second open part of the second surface treating area may be formed on the solder resist layer 130.

In this case, the mask layer may be formed of a dry film.

Next, as shown in FIG. 5, the first open part (132 of FIG. 2) on the second surface treating area may be subjected to the laser machining to expose the circuit layer 120 of the second surface treating area, thereby forming the second open part 134 on the second surface treating area.

In this case, as shown in FIG. 5, the second open part 134 on the second surface treating area may be formed to be equal to the size of the first open part 132 on the second surface treating area based on a length direction of the substrate.

However, the same herein means substantially the same size in consideration of a manufacturing error, a measuring error of the thickness having exactly the same dimension in a mathematical meaning.

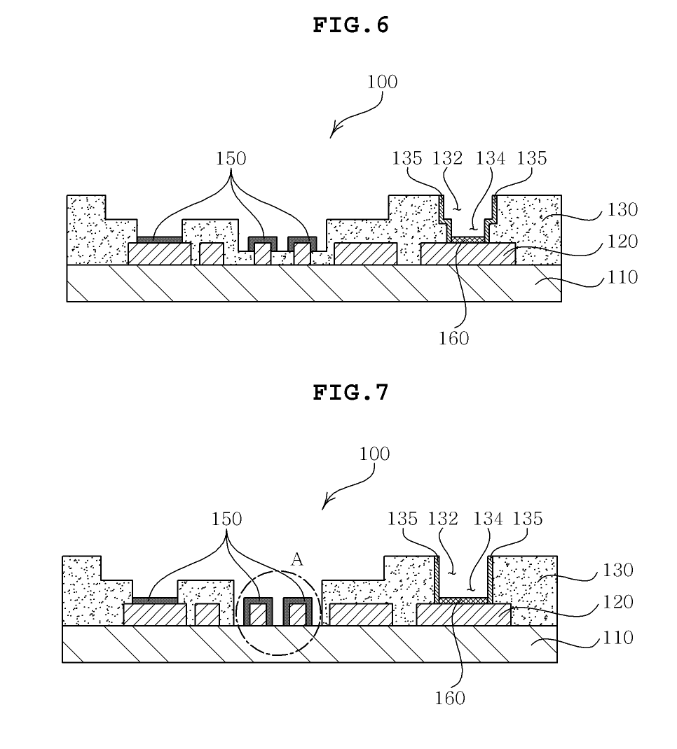

Meanwhile, as shown in FIG. 6, the second open part 134 on the second surface treating area may be formed so as to be smaller than the size of the first open part 132 on the second surface treating area based on a length direction of the substrate.

The size of the open part may be variously changed according to an operator demand in addition to the foregoing structure.

Next, as shown in FIG. 5, the first open part 132 and the second open part 134 on the second surface treating area may be subjected to the desmear process.

In this case, as a result of performing the desmear process, as shown in FIG. 5, a desmear treating layer 135 may be formed.

Next, as shown in FIG. 5, a second surface treating layer 160 may be formed on the exposed circuit layer 120 of the second surface treating area.

The second surface treating layer 160 is not particularly limited to if known to those skilled in the art and may be formed, for example, by electro gold plating, immersion gold plating, Organic Solderability Preservative (OSP), immersion tin plating, immersion silver plating, electroless nickel and immersion gold (ENIG), Direct Immersion Gold (DIG) plating, Hot Air Solder Leveling (HASL), Electroless Nickel Electroless Palladium Immersion Gold (ENEPIG), or Electroless Palladium Immersion Gold (EPIG), and the like.

In this case, the first surface treating layer 150 and the second surface treating layer 160 may be formed of different materials.

The solder resist layer 130 may be formed with a step shape corresponding to the step open part 133 on the first surface treating area by the foregoing manufacturing process.

In addition, as shown in FIG. 6, the solder resist layer 130 corresponding to the second surface treating area may also be formed with the step structure.

A multi-stage multi structure having the step structure according to the preferred embodiment of the present invention is applied to the printed circuit board for the package on package (PoP) and thus, can be easily bonded with the semiconductor device or the electronic parts.

The method for manufacturing a printed circuit board according to the preferred embodiments of the present invention can provide the printed circuit board for the package on package capable of easily mounting the semiconductor device by forming the solder resist having the step structure using the exposing and developing processes or the laser machining.

Although the preferred embodiments of the present invention have been disclosed for illustrative purposes, they are for specifically explaining the present invention. Therefore, those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims.

What is claimed is:

1. A method for manufacturing a printed circuit board, comprising:
preparing a base substrate on which a circuit layer segmented into a first surface treating area and a second surface treating area is formed;
forming a solder resist layer on the base substrate, including the circuit layer;
forming a first open part of the first surface treating area and a first open part of the second surface treating area by performing exposing and developing processes on solder resist layers corresponding to the first surface treating area and the second surface treating area;
forming a step open part of the first surface treating area exposing the circuit layer of the first surface treating area by performing the exposing and developing processes on the first open part of the first surface treating area;
forming the first surface treating layer on the exposed circuit layer of the first surface treating area;
forming a second open part of the second surface treating area by performing laser machining on the first open part of the second surface treating area to expose the circuit layer of the second surface treating area; and
forming the second surface treating layer on the exposed circuit layer of the second surface treating area,
wherein the solder resist layer is formed with a step shape corresponding to the step open part of the first surface treating area.

2. The method as set forth in claim 1, further comprising: after the forming of the solder resist layer and before the forming of the first open part of the first surface treating area and the first open part of the second surface treating area,
removing the solder resist layer based on a thickness direction of a substrate by performing the exposing and developing processes on the overall surface of an upper portion of the solder resist layer to arbitrarily reduce a thickness thereof.

3. The method as set forth in claim 1, further comprising: after the forming of the first surface treating layer and before the forming of the second open part of the second surface treating area,
forming a mask layer having an open part corresponding to the second open part of the second surface treating area on the solder resist layer.

4. The method as set forth in claim 3, wherein the mask layer is formed of a dry film.

5. The method as set forth in claim 1, wherein in the forming of the step open part of the first surface treating area,
the step open part of the first surface treating area is formed so as to expose an upper surface and a side of the circuit layer of the first surface treating area.

6. The method as set forth in claim 1, wherein in the forming of the second open part of the second surface treating area,
the second open part of the second surface treating area is formed to be equal to a size of the first open part of the second surface treating area based on a length direction of the substrate.

7. The method as set forth in claim 1, wherein in the forming of the second open part of the second surface treating area,
the second open part of the second surface treating area is formed to be smaller than a size of the first open part of the second surface treating area based on a length direction of the substrate.

8. The method as set forth in claim 1, further comprising: after the forming of the second opening part of the second surface treating area and before the forming of the second surface treating layer on the exposed circuit layer of the second surface treating area,
performing a desmear process on the first open part and the second open part of the second surface treating area.

9. A method for manufacturing a printed circuit board, comprising:
preparing a base substrate on which a circuit layer segmented into a first surface treating area and a second surface treating area is formed;
forming a solder resist layer on the base substrate, including the circuit layer;
forming a first open part of the first surface treating area and a first open part of the second surface treating area by performing laser machining on solder resist layers corresponding to the first surface treating area and the second surface treating area;
forming a step open part of the first surface treating area exposing the circuit layer of the first surface treating area by performing the laser machining on the first open part of the first surface treating area;
forming the first surface treating layer on the exposed circuit layer of the first surface treating area;
forming a second open part of the second surface treating area by performing laser machining on the first open part of the second surface treating area to expose the circuit layer of the second surface treating area; and
forming the second surface treating layer on the exposed circuit layer of the second surface treating area,
wherein the solder resist layer is formed with a step shape corresponding to the step open part of the first surface treating area.

10. The method as set forth in claim 9, further comprising: after the forming of the solder resist layer and before the forming of the first open part of the first surface treating area and the first open part of the second surface treating area,
removing the solder resist layer based on a thickness direction of a substrate by performing the exposing and developing processes on the overall surface of an upper portion of the solder resist layer to arbitrarily reduce a thickness thereof.

11. The method as set forth in claim 9, further comprising: after the forming of the solder resist layer and before the forming of the first open part of the first surface treating area and the first open part of the second surface treating area,
removing the solder resist layer based on a thickness direction of a substrate by performing the laser machining on the overall surface of an upper portion of the solder resist layer to arbitrarily reduce a thickness thereof.

12. The method as set forth in claim 9, further comprising: after the forming of the first surface treating layer and before the forming of the second open part of the second surface treating area,
forming a mask layer having an open part corresponding to the second open part of the second surface treating area on the solder resist layer.

13. The method as set forth in claim 12, wherein the mask layer is formed of a dry film.

14. The method as set forth in claim 9, wherein in the forming of the step open part of the first surface treating area,
the step open part of the first surface treating area is formed so as to expose an upper surface and a side of the circuit layer of the first surface treating area.

15. The method as set forth in claim 9, wherein in the forming of the second open part of the second surface treating area,
the second open part of the second surface treating area is formed to be equal to a size of the first open part of the second surface treating area based on a length direction of the substrate.

16. The method as set forth in claim 9, wherein in the forming of the second open part of the second surface treating area,
the second open part of the second surface treating area is formed to be smaller than a size of the first open part of the second surface treating area based on a length direction of the substrate.

17. The method as set forth in claim 9, further comprising: after the forming of the step opening part of the first surface treating area and before the forming of the first surface treating layer on the exposed circuit layer of the first surface treating area,
performing a desmear process on the step open part of the first surface treating area.

18. The method as set forth in claim 9, further comprising: after the forming of the second opening part of the second surface treating area and before the forming of the second surface treating layer on the exposed circuit layer of the second surface treating area,
performing a desmear process on the first open part and the second open part of the second surface treating area.
